(19) United States
(12) Patent Application Publication
(10) Pub. No.: US 2026/0096113 A1
(43) Pub. Date: Apr. 2, 2026

(54) CAPACITOR STRUCTURE, MEMORY DEVICE AND MANUFACTURING METHOD THEREOF

(71) Applicant: Samsung Electronics Co., Ltd., Suwon-si (KR)

(72) Inventors: Kyooho JUNG, Suwon-si (KR); Donghyun KIM, Suwon-si (KR); Jooho LEE, Suwon-si (KR); Duk Hyun CHOE, Suwon-si (KR)

(73) Assignee: Samsung Electronics Co., Ltd., Suwon-si (KR)

(21) Appl. No.: 19/193,604

(22) Filed: Apr. 29, 2025

(30) Foreign Application Priority Data
Sep. 30, 2024 (KR) 10-2024-0133196

(51) Int. Cl. H10D 1/68; H10B 12/00; H10D 1/00

(52) U.S. Cl. CPC H10D 1/716; H10B 12/033; H10B 12/315; H10D 1/041

(57) ABSTRACT

According to at least one embodiment of the present disclosure, there is provided a capacitor structure including a lower electrode including a first lower electrode and a second lower electrode, an upper electrode, a supporter in contact with the first lower electrode and the second lower electrode, a dielectric layer between the lower electrode and the upper electrode, a lower interface layer between the lower electrode and the dielectric layer, the lower interface layer including a first material that is a conductive material and includes nitrogen (N), and a supporter interface layer between the supporter and the dielectric layer, and the supporter interface layer including a second material, the second material being an insulator and including nitrogen (N).

### CROSS-REFERENCE TO RELATED APPLICATION

This application claims priority to Korean Patent Application No. 10-2024-0133196 filed on Sep. 30, 2024 and all the benefits accruing therefrom under 35 U.S.C. § 119, the contents of which are incorporated by reference in their entirety.

### BACKGROUND

The present disclosure relates to a capacitor structure, a memory device, and a manufacturing method thereof.

In dynamic random-access memory (DRAM) devices, each unit device typically has a structure including one transistor and one capacitor. To achieve higher degrees of integration of DRAM devices, capacitors having higher electrostatic capacitance and reduced leakage current are being developed.

### SUMMARY

The present disclosure is provided to improve a situation where leakage current occurs due to high defect concentration at an interface between an electrode and a dielectric layer or the like in a capacitor having a metal-ferroelectric-metal (MFM) or metal-insulator-metal (MIM) structure and improve the phenomenon of capacity deterioration in a negative voltage range due to a metal oxide layer on an electrode that is generated during capacitor manufacturing.

The effects of present disclosure are not limited to those mentioned above, and other effects not mentioned will be clearly understood by those skilled in the art from the following description.

According to at least one embodiment of the present disclosure, a capacitor structure includes a lower electrode including a first lower electrode and a second lower electrode, an upper electrode, a supporter in contact with the first lower electrode and the second lower electrode, a dielectric layer between the lower electrode and the upper electrode, a lower interface layer between the lower electrode and the dielectric layer, the lower interface layer including a first material; the first material being a conductor and including nitrogen (N), and a supporter interface layer between the supporter and the dielectric layer, the supporter interface layer including a second material, the second material being an insulator and including nitrogen (N).

According to another embodiment of the present disclosure, a memory device includes a capacitor structure in accordance with the example embodiment of the present disclosure and one or more transistors, in which the transistors are electrically connected to the capacitor structure.

According to still another embodiment of the present disclosure, a capacitor structure includes a lower electrode including a first lower electrode and a second lower electrode, an upper electrode, a supporter in contact with the first lower electrode and the second lower electrode, a dielectric layer between the lower electrode and the upper electrode, a lower interface layer between the lower electrode and the dielectric layer, the lower interface layer including at least one of a nitride or an oxynitride including a first element (M₁), and a supporter interface layer between the supporter and the dielectric layer, the supporter interface layer including at least one of a nitride or an oxynitride including a second element (M₂), the M₁ includes one or more of titanium (Ti), vanadium (V), chromium (Cr), manganese (Mn), iron (Fe), cobalt (Co), nickel (Ni), copper (Cu), niobium (Nb), molybdenum (Mo), ruthenium (Ru), palladium (Pd), indium (In), antimony (Sb), tantalum (Ta), tungsten (W), iridium (Ir), platinum (Pt), gold (Au), or polonium (Po), and the M₂ includes one or more of aluminum (Al), gallium (Ga), germanium (Ge), tin (Sn), silicon (Si), and boron (B).

According to yet another embodiment of the present disclosure, a method of manufacturing a capacitor structure, includes forming a lower electrode including a first lower electrode including a first element (M₁) and a second lower electrode spaced apart from the first lower electrode; forming a supporter in contact with the first lower electrode and the second lower electrode, forming a first nitride layer on the lower electrode; forming a second nitride layer on the supporter, forming a dielectric layer on the first nitride layer and the second nitride layer, forming an upper electrode on the dielectric layer, and diffusing the M₁ included in the lower electrode into the first nitride layer, the second nitride layer includes a second element (M₂), the first nitride layer includes a third element (M₃), the M₁ including one or more of titanium (Ti), vanadium (V), chromium (Cr), manganese (Mn), iron (Fe), cobalt (Co), nickel (Ni), copper (Cu), niobium (Nb), molybdenum (Mo), ruthenium (Ru), palladium (Pd), indium (In), antimony (Sb), tantalum (Ta), tungsten (W), iridium (Ir), platinum (Pt), gold (Au), or polonium (Po), and the M₂ and M₃ each independently including one or more of aluminum (Al), gallium (Ga), germanium (Ge), tin (Sn), silicon (Si), or boron (B).

Details of other embodiments are included in the Detailed Description and drawings.

### BRIEF DESCRIPTION OF THE DRAWINGS

The drawings shown in the present disclosure are according to embodiments, and ratios of the width, height or thickness of each component is for describing the present disclosure in detail, and the ratio may be different from the actual ones. In addition, each component illustrated in the drawings may be exaggerated to describe the present disclosure in detail. In addition, in a coordinate system shown in the drawing, each axis may can be perpendicular to the others, a direction pointed by an arrow may be a +direction, and a direction opposite to the direction pointed by the arrow (a direction rotated by 180 degrees) may be a −direction:

FIG. 1 schematically illustrates at least a portion of a capacitor structure according to at least one embodiment of the present disclosure;

FIG. 2 is an enlarged view of part P in FIG. 1;

FIG. 3 is an enlarged view of part Q in FIG. 1;

FIGS. 4 and 5 are views for describing features of the capacitor structure according to at least one embodiment of the present disclosure;

FIG. 6 schematically illustrates at least a portion of the capacitor structure according to at least one embodiment of the present disclosure;

FIG. 7 is an enlarged view of part R in FIG. 6;

FIGS. 8 to 13 are views for describing a method of manufacturing a capacitor structure according to at least one embodiment of the present disclosure;

FIG. 14 schematically illustrates at least a portion of a memory device according to at least one embodiment of the present disclosure;

FIG. 15 schematically illustrates at least a portion of the memory device according to at least one embodiment of the present disclosure;

FIG. 16 is a cross-sectional view taken along lines A-A′ and B-B′ in FIG. 15;

FIG. 17 schematically illustrates at least a portion of a memory device according to at least one embodiment of the present disclosure; and

FIG. 18 schematically illustrates at least a portion of the memory device according to at least one embodiment of the present disclosure.

### DETAILED DESCRIPTION OF EMBODIMENTS

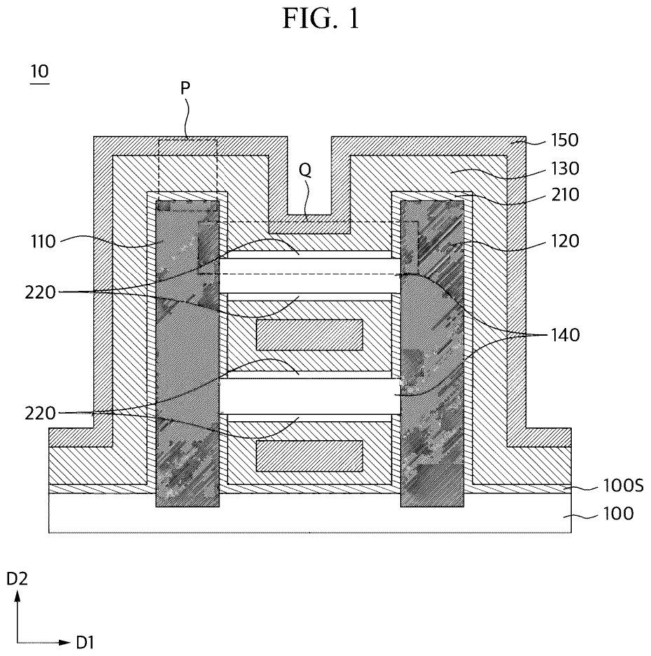

Also, when a component is described as being “above” another component in the present specification, it is meant that the component is present above the another component in a direction perpendicular to a surface of a substrate (e.g., a second direction D2 in FIG. 1), and it is to be understood that the components may be in direct contact or connected or still another component is present between the components. Further, when a component is described as being “below” another component in the present specification, it is meant that the component is present below the another component in a direction perpendicular to a surface of a substrate (e.g., the second direction D2 in FIG. 1), and it is to be understood that the components may be in direct contact or connected or still another component is present between the components. In addition, in the description below, expressions such as an upper side, an upper surface, a lower side, a lower surface, a side surface, a front surface, a rear surface, or the like, are expressed based on a direction shown in the drawing, and may be differently expressed when the direction of a corresponding object changes. Thereby such spatially relative terms encompass different orientations of the device in use or operation in addition to the orientation depicted in the figures, and that the device may be otherwise oriented (rotated 90 degrees or at other orientations) and the spatially relative terms used herein interpreted accordingly.

The shape or size of elements in drawings may be exaggerated for clearer description. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

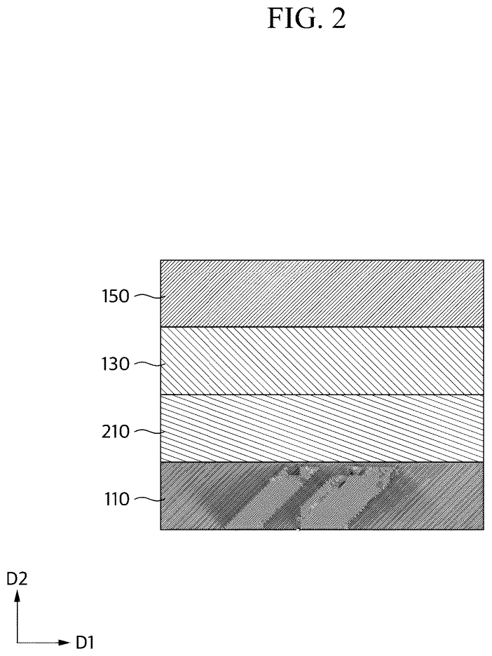

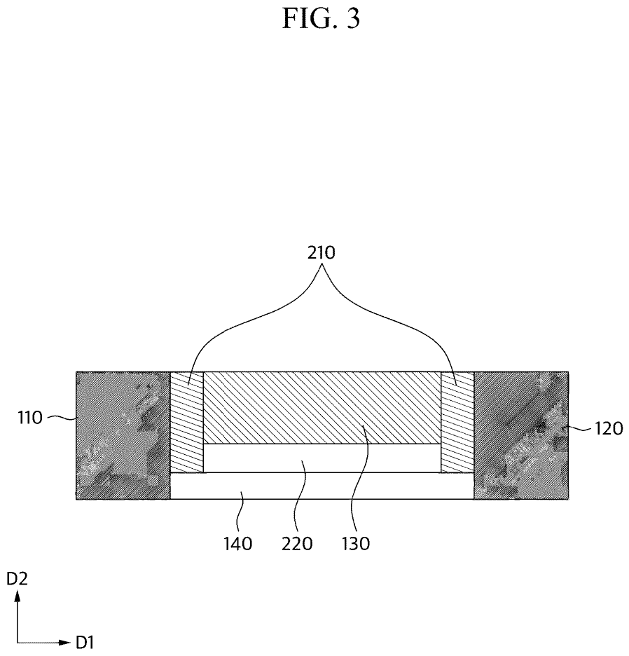

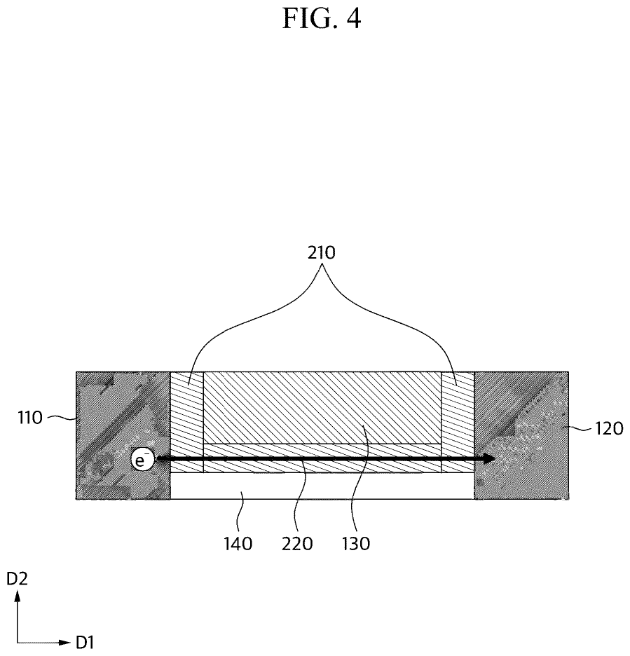

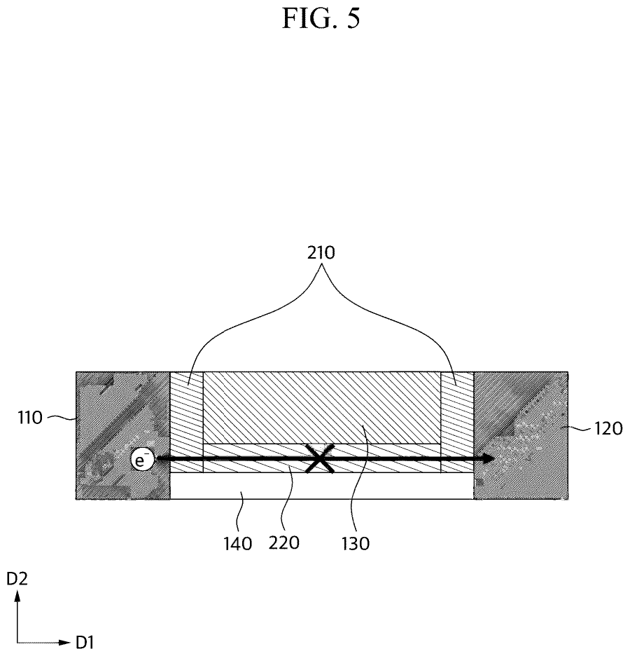

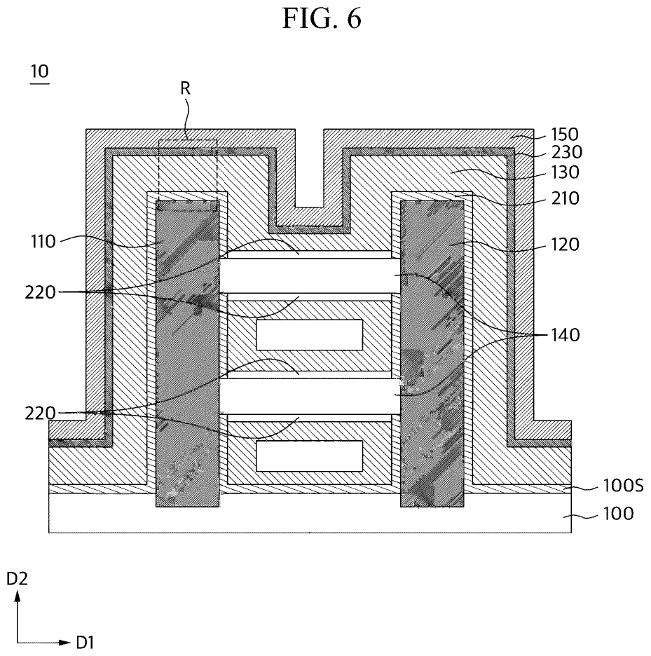

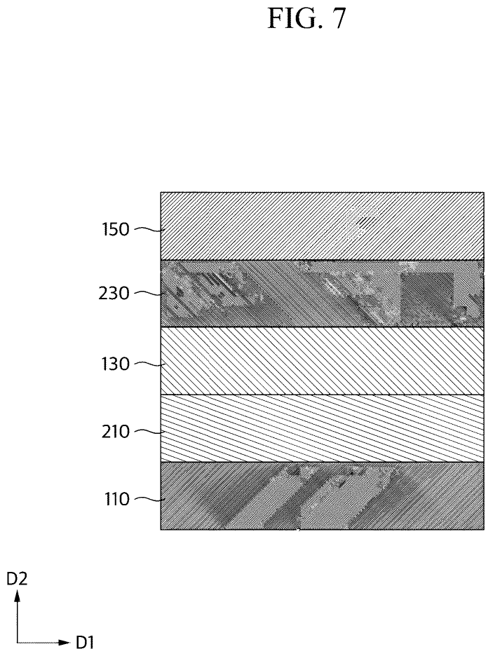

FIG. 1 schematically illustrates at least a portion of a capacitor structure 10 according to at least one embodiment of the present disclosure. FIG. 2 is an enlarged view of part P in FIG. 1. FIG. 3 is an enlarged view of part Q in FIG. 1. FIGS. 4 and 5 are views for describing features of the capacitor structure 10 according to at least one embodiment of the present disclosure. FIG. 6 schematically illustrates at least a portion of the capacitor structure 10 according to at least one embodiment of the present disclosure. FIG. 7 is an enlarged view of portion R in FIG. 6.

The capacitor structure 10 according to at least one embodiment of the present disclosure may be included in, for example, a memory device. In at least one example, the memory device may include the capacitor structure 10 and may include one or more transistors (not illustrated). Here, the transistors may be electrically connected to the capacitor structure 10. For example, the memory device may be a volatile memory device. The volatile memory device may be, for example, a dynamic RAM (DRAM). The DRAM may be, for example, a three-dimensional DRAM. In at least one example, the memory device may be a memory device including a vertical channel transistor (VCT). In at least one example, the memory device may be a DRAM having a vertical stacked structure.

The capacitor structure 10 may include a substrate structure 100, a lower electrode including a first lower electrode 110 and a second lower electrode 120, a dielectric layer 130, a supporter 140, an upper electrode 150, a lower interface layer 210, and a supporter interface layer 220.

The substrate structure 100 may be and/or include a substrate. The substrate may include at least one of a semiconductor material and/or an insulating material. For example, the substrate may be and/or include at least one of an elemental semiconductor substrate (e.g., a silicon substrate, a germanium substrate, etc.), a plastic substrate, a glass substrate, a compound semiconductor substrate, a ceramic substrate, a silicon-on-insulator (SOI) substrate, and/or the like. In at least one example, the lower electrode including the first lower electrode 110 and the second lower electrode 120, the dielectric layer 130, the supporter 140, and the upper electrode 150 may be disposed on (e.g., above) a surface 100S of the substrate structure 100.

According to some embodiments, the substrate structure 100 may include, although not separately illustrated, an impurity region due to doping, a peripheral circuit for selecting and controlling an electronic element such as a transistor or a memory cell, and/or the like.

In at least one example, a first direction D1 may be a horizontal direction parallel to the surface 100S of the substrate structure 100 as illustrated in FIG. 1. A second direction D2 may be a direction intersecting the first direction D1, and specifically, the second direction D2 may be a vertical direction perpendicular to the surface 100S of the substrate structure 100 as illustrated in FIG. 1. A third direction D3 may be a second horizontal direction that intersects the first direction D1 but which is also parallel to the surface 100S of the substrate structure 100.

The lower electrode may include the first lower electrode 110 and the second lower electrode 120. In at least one example, the first lower electrode 110 and the second lower electrode 120 may be spaced apart from each other in a horizontal direction (e.g., the first direction D1).

In at least one example, the first lower electrode 110 and the second lower electrode 120 may be extended to be long in the second direction D2. For example, in at least one example, each of the first lower electrode 110 and the second lower electrode 120 may have a length extending in the second direction D2 greater than a width extending in the first direction D1 and/or the third direction D3. In at least one example, each of the first lower electrode 110 and the second lower electrode 120 may have, for example, a pillar shape.

In at least one example, the first lower electrode 110 and the second lower electrode 120 may each independently include a conductive material such as a zero-band gap material and/or a material with an equivalent conductivity (e.g., 10⁵ S/m or more, and/or 10⁶ S/m or more when measured at room temperature). For example, the first lower electrode 110 and the second lower electrode 120 may each independently include, but are not limited to, one or more of a doped semiconductor material, a conductive metal nitride (e.g., titanium nitride, tantalum nitride, niobium nitride, tungsten nitride, etc.), a conductive metal oxynitride (e.g., titanium oxynitride, tantalum oxynitride, niobium oxynitride, tungsten oxynitride, etc.), a metal (e.g., copper, aluminum, ruthenium, iridium, titanium, tantalum, etc.), and a conductive metal oxide (e.g., iridium oxide, niobium oxide, etc.), and/or the like. In at least one example, the first lower electrode 110 and the second lower electrode 120 may each independently include one or more of titanium nitride (TiN), niobium nitride (NbN), and/or molybdenum nitride (MoN). In at least one example, the first lower electrode 110 and the second lower electrode 120 may include titanium nitride (TiN). In at least one example, the first lower electrode 110 and the second lower electrode 120 may include the same material.

In at least one example, each of the first lower electrode 110 and the second lower electrode 120 may include a lower electrode metal element M_{be}. In at least one example, the lower electrode metal element M_{be} may include one or more of titanium (Ti), vanadium (V), chromium (Cr), manganese (Mn), iron (Fe), cobalt (Co), nickel (Ni), copper (Cu), aluminum (Al), gallium (Ga), germanium (Ge), niobium (Nb), molybdenum (Mo), technetium (Tc), ruthenium (Ru), palladium (Pd), silver (Ag), cadmium (Cd), indium (In), tin (Sn), antimony (Sb), tantalum (Ta), tungsten (W), rhenium (Re), osmium (Os), iridium (Ir), platinum (Pt), gold (Au), mercury (Hg), lead (Pb), bismuth (Bi), and/or polonium (Po). In at least one example, the lower electrode metal element M_{be} may include one or more of titanium (Ti), niobium (Nb), and/or molybdenum (Mo). In at least one example, the lower electrode metal element M_{be} may include titanium (Ti).

The supporter 140 may be in contact with the first lower electrode 110 and the second lower electrode 120. For example, in at least one example, the supporter 140 may support the first lower electrode 110 and the second lower electrode 120 by bringing the first lower electrode 110 and the second lower electrode 120 into contact with each other. In at least one example, there may be one or more supporters 140. In FIG. 1, two supporters 140 are illustrated, but this is only one example, and the examples are not limited thereto. When there are two or more supporters 140, a length of each supporter 140 extended in the second direction D2 may be the same as or different from the other, and each supporter 140 may be spaced apart from the other (for example, in the second direction D2). In at least one example, the supporters 140 may be disposed parallel to the first direction D1 to stably support the first lower electrode 110 and the second lower electrode 120.

In at least one example, an upper surface of the supporter 140 may be disposed to be lower in the second direction D2 than at least one of an upper surface of the first lower electrode 110 and an upper surface of the second lower electrode 120. Specifically, the upper surface of the supporter 140 may be closer to the surface 100S of the substrate structure in the second direction D2 than at least one of the upper surface of the first lower electrode 110 and the upper surface of the second lower electrode 120. In at least one example, the upper surface of the supporter 140 may be disposed at the same position as at least one of the upper surface of the first lower electrode 110 and the upper surface of the second lower electrode 120 in the second direction D2.

In at least one example, the supporter 140 may include an insulating material, such as one or more of silicon nitride (SiNₓ), silicon carbonitride (SiCN), silicon boron nitride (SiBN), silicon carbonate (SiCO), silicon oxynitride (SiON), silicon oxide (SiOₓ), and/or silicon oxycarbonitride (SiOCN). In at least one example, the supporter 140 may include silicon nitride.

The upper electrode 150 is spaced apart from the first lower electrode 110 and the second lower electrode 120 with the dielectric layer 130 therebetween. The upper electrode 150 is illustrated as a single film, but the examples are not limited thereto; for example, the upper electrode 150 may be a multilayer film.

In at least one example, the upper electrode 150 may include a conductive material (or a conductor) such as a zero-band gap material and/or a material with an equivalent conductivity. For example, the upper electrode 120 may include one or more of a doped semiconductor material, a conductive metal nitride (e.g., titanium nitride, tantalum nitride, niobium nitride, or tungsten nitride), a conductive metal oxynitride (e.g., titanium oxynitride, tantalum oxynitride, niobium oxynitride, or tungsten oxynitride), a metal (e.g., ruthenium, iridium, titanium, or tantalum), and/or a conductive metal oxide (e.g., iridium oxide or niobium oxide), but is not limited thereto. In at least one example, the upper electrode 150 may include one or more of titanium nitride (TiN), niobium nitride (NbN), and/or molybdenum nitride (MoN). In at least one example, the upper electrode 150 may include titanium nitride (TiN).

In at least one example, the upper electrode 150 may include an upper electrode metal element Mᵤₑ. In at least one example, the upper electrode metal element Mᵤₑ may include one or more of titanium (Ti), vanadium (V), chromium (Cr), manganese (Mn), iron (Fe), cobalt (Co), nickel (Ni), copper (Cu), aluminum (Al), gallium (Ga), germanium (Ge), niobium (Nb), molybdenum (Mo), technetium (Tc), ruthenium (Ru), palladium (Pd), silver (Ag), cadmium (Cd), indium (In), tin (Sn), antimony (Sb), tantalum (Ta), tungsten (W), rhenium (Re), osmium (Os), iridium (Ir), platinum (Pt), gold (Au), mercury (Hg), lead (Pb), bismuth (Bi), and/or polonium (Po). In at least one example, the upper electrode metal element Mᵤₑ may include one or more of titanium (Ti), niobium (Nb), and/or molybdenum (Mo). In at least one example, the upper electrode metal element Mᵤₑ may include titanium (Ti).

The dielectric layer 130 is disposed between the lower electrode (including the first lower electrode 110 and the second lower electrode 120) and the upper electrode 150. In at least one example, the dielectric layer 130 may be formed on at least a portion of the first lower electrode 110, the second lower electrode 120, and the supporter 140.

In at least one example, referring to FIG. 1, the dielectric layer 130 may be spaced apart from the lower electrode. In at least one example, the lower interface layer 210 may be disposed between the dielectric layer 130 and the lower electrode.

In at least one example, the dielectric layer 130 may be formed on at least a portion of the upper electrode 150. In at least one example, the dielectric layer 130 may be spaced apart from the upper electrode 150. In at least one example, the capacitor structure 10 may include an upper interface layer 230 disposed between the dielectric layer 130 and the upper electrode 150 (discussed in further detail below).

In at least one example, the dielectric layer 130 may be spaced apart from the supporter 140. For example, in at least one example, the supporter interface layer 220 may be disposed between the dielectric layer 130 and the supporter 140.

In at least one example, the dielectric layer 130 may include an insulating material (or an insulator). For example, the dielectric layer 130 may include, but is not limited to, one or more of silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. The dielectric layer 130 is illustrated as a single film, but the dielectric layer is not limited thereto; for example, the dielectric layer 130 may be a multilayer film.

In at least one example, the dielectric layer 130 may include a paraelectric. In at least one example, the dielectric layer 130 may include a stacked structure including, e.g., a first metal oxide layer, a second metal oxide layer, and a third metal oxide layer. In at least one example, the first metal oxide layer may include the same metal oxide as the third metal oxide layer and may include a different metal oxide than the second metal oxide layer. For example, the first metal oxide layer and the third metal oxide layer may include zirconium oxide, and the second metal oxide layer may include aluminum oxide.

In at least one example, the dielectric layer 130 may include a ferroelectric. In at least one example, a ferroelectric may have spontaneous polarization characteristics due to application of an electric field, and may have remnant polarization characteristics even in the absence of the electric field after having spontaneous polarization characteristics. In at least one example, the ferroelectric may include a compound including one or more of hafnium (Hf) and zirconium (Zr) and having ferroelectric properties. For example, the ferroelectric may comprise a material having a ferroelectric phase as a primary phase. In at least one example, the ferroelectric may include hafnium oxide (HfOₓ) that is a compound including hafnium (Hf), zirconium oxide (ZrOₓ) that is a compound including zirconium (Zr), or hafnium-zirconium oxide (HZO) that is a compound including hafnium (Hf) and zirconium (Zr). In at least one example, the ferroelectric is not limited to the compounds described above and may include one or more of BaTiO₃, PbTiO₃, BiFeO₃, SrTiO₃, PbMgNdO₃, PbMgNbTiO₃, PbZrNbTiO₃, PbZrTiO₃, KnbO₃, LiNbO₃, GeTe, LiTaO₃, KnaNbO₃, BaSrTiO₃, HF0·5Zr0·5O₂, PbZrₓTi₁₋ₓO₃ (0<x<1), Ba(Sr, Ti)O₃, Bi₄-xLaₓTi₃O₁₂ (0<x<1), SrBi₂Ta₂O₉, Pb₅Ge₅O₁₁, SrBi₂Nb₂O₉, and/or YmnO₃. In at least one example, the ferroelectric phase may include an orthorhombic crystal system. In at least one example, the ferroelectric may include a compound doped with an impurity, and the impurity may include one or more of carbon (C), silicon (Si), magnesium (Mg), aluminum (Al), yttrium (Y), nitrogen (N), germanium (Ge), tin (Sn), gadolinium (Gd), lanthanum (La), scandium (Sc), and/or strontium (Sr).

The lower interface layer 210 may be disposed between the lower electrode including the first lower electrode 110 and the second lower electrode 120 and the dielectric layer 130. In at least one example, the lower interface layer 210 may include a conductive material.

In the present specification, conductivity may mean smooth flow of electricity, and the conductive material may mean, for example, a material having a conductivity of 10⁵ S/m or more or 10⁶ S/m or more when measured at room temperature. In this case, the conductivity may be measured based on ASTM E 1004, but is not limited thereto.

In at least one example, the lower interface layer 210 may include a first material. In at least one example, the first material may be a conductive material and may include nitrogen (N). In at least one example, the first material may include nitrogen (N) and oxygen (O). In at least one example, the lower interface layer 210 may include the first material that is a conductive material. In at least one example, the first material may include one or more of aluminum (Al), gallium (Ga), germanium (Ge), tin (Sn), silicon (Si), and/or boron (B).

In at least one example, the lower electrode may include the lower electrode metal element M_{be}, and the first material may include the lower electrode metal element M_{be}. In at least one example, the first material may include the lower electrode metal element M_{be} in a state in which the lower electrode metal element M_{be} is doped.

In at least one example, in the lower interface layer 210, the concentration of the lower electrode metal element M_{be} may gradually decrease with distance from the lower electrode.

In at least one example, the lower interface layer 210 may include the lower electrode metal element M_{be} of 10 atomic percent (at %) or less, 9 at % or less, 8 at % or less, 7 at % or less, 6 at % or less, or 5 at % or less relative to the total number of elements excluding nitrogen (N). In this way, in the capacitor structure 10, the lower interface layer 210 may reduce leakage current and/or prevent leakage current from increasing while maintaining conductivity. In at least one example, when the first material included in the lower interface layer 210 includes nitrogen (N) and oxygen (O), the lower interface layer 210 may include the lower electrode metal element M_{be} in an amount of 10 at % or less, 9 at % or less, 8 at % or less, 7 at % or less, 6 at % or less, or 5 at % or less relative to the total number of elements excluding nitrogen (N) and oxygen (O).

The supporter interface layer 220 may be disposed between the supporter 140 and the dielectric layer 130. In at least one example, the supporter interface layer 220 may include an insulating material.

In the present specification, insulating may mean non-conductive or weakly conductive, and the insulating material may mean a non-conductive or weakly conductive material. The insulating material may mean, for example, a material having a conductivity of 10⁻⁶ S/m or less, 10⁻⁹ S/m or less, or 10⁻¹⁰ S/m or less when measured at room temperature. In this case, the conductivity may be measured based on ASTM E 1004, but is not limited thereto.

In at least one example, the supporter interface layer 220 may include a second material. In at least one example, the second material may be an insulating material and may include nitrogen (N). In at least one example, the second material may include nitrogen (N) and oxygen (O). In at least one example, the supporter interface layer 220 may include the second material that is an insulating material. In at least one example, the second material may include one or more of aluminum (Al), gallium (Ga), germanium (Ge), tin (Sn), silicon (Si), and/or boron (B).

In at least one example, the lower electrode may include the lower electrode metal element M_{be}. In at least one example, the supporter interface layer 220 may not substantially include the lower electrode metal element M_{be}. That the supporter interface layer 220 does not substantially include the lower electrode metal element M_{be} may mean that the supporter interface layer includes 0.1 at % or less, 0.05 at % or less, or 0.01 at % or less of the total number of elements excluding nitrogen (N). In another example, that the supporter interface layer 220 does not substantially include the lower electrode metal element M_{be} may mean that the lower electrode metal element M_{be} of the lower electrode is not intentionally diffused into the supporter interface layer 220 through heat treatment during a manufacturing process of the capacitor structure 10. In at least one example, the supporter interface layer 220 may not substantially include the lower electrode metal element M_{be} derived from the lower electrode, but may include a metal element identical to the lower electrode metal element M_{be} but not derived from the lower electrode.

The lower interface layer 210 according to the embodiment of the present disclosure may include a nitride or an oxynitride including M₁. In at least one example, M₁ may include one or more of titanium (Ti), vanadium (V), chromium (Cr), manganese (Mn), iron (Fe), cobalt (Co), nickel (Ni), copper (Cu), niobium (Nb), molybdenum (Mo), technetium (Tc), ruthenium (Ru), palladium (Pd), silver (Ag), cadmium (Cd), indium (In), antimony (Sb), tantalum (Ta), tungsten (W), rhenium (Re), osmium (Os), iridium (Ir), platinum (Pt), gold (Au), mercury (Hg), lead (Pb), bismuth (Bi), and/or polonium (Po). In at least one example, the M₁ may include one or more of titanium (Ti), niobium (Nb), and/or molybdenum (Mo). In at least one example, the description of the M₁ may refer to the content of the lower electrode metal element M_{be} mentioned above, unless it is contradictory.

In at least one example, the lower electrode may include M₁. In at least one example, the first lower electrode 110 and the second lower electrode 120 may include the same element, and the first lower electrode 110 and the second lower electrode 120 may include M₁. In at least one example, the lower electrode may include the first lower electrode 110 and the second lower electrode 120, each including M₁.

In at least one example, in the lower interface layer 210, the concentration of the M₁ may gradually decrease with distance from the lower electrode.

In at least one example, the lower interface layer 210 may further include one or more M₃ elements of aluminum (Al), gallium (Ga), germanium (Ge), tin (Sn), silicon (Si), and/or boron (B).

In at least one example, the lower interface layer 210 may include the M₁ in an amount of 10 at % or less, 9 at % or less, 8 at % or less, 7 at % or less, 6 at % or less, or 5 at % or less relative to the total number of elements of the M₁ and M₃. In this way, in the capacitor structure 10, the lower interface layer 210 may prevent leakage current from increasing while maintaining conductivity.

The supporter interface layer 220 according to the embodiment of the present disclosure may include a nitride or an oxynitride including M₂. In at least one example, the M₂ may include one or more of aluminum (Al), gallium (Ga), germanium (Ge), tin (Sn), silicon (Si), and/or boron (B). In at least one example, the M₂ may be the same element as the M₃.

The capacitor structure 10, according to at least some embodiments, may include an oxide layer (not shown) disposed between the lower interface layer 210 and the lower electrode. In at least one example, the oxide layer may include the lower electrode metal element M_{be} included in the lower electrode. In at least one example, the oxide layer may be formed by the lower electrode metal element M_{be} bonded to oxygen atoms. In at least one example, the oxygen atoms bonded to the lower electrode metal element M_{be} may be derived from ozone (O₃) that may be used during the manufacturing process of the capacitor structure 10, but is not limited thereto. In at least one example, the thickness of the oxide layer may be, but is not limited to, 0.1 nm or less.

Referring to FIG. 4, as one comparative example of the present disclosure, an electron movement aspect is shown when the supporter interface layer 220 includes a conductive material. Since the supporter interface layer 220 on the supporter 140 in contact with the first lower electrode 110 and the second lower electrode 120 includes the conductive material, electrons may move from the first lower electrode 110 to the second lower electrode 120 or from the second lower electrode 120 to the first lower electrode 110. This makes two electrodes and capacitors to be separated connecting each other, which causes a bridge defect.

Referring to FIG. 5, in the capacitor structure 10 according to at least one embodiment of the present disclosure, since the supporter interface layer 220 on the supporter 140 in contact with the first lower electrode 110 and the second lower electrode 120 includes an insulating material, it is difficult for electrons to move from the first lower electrode 110 to the second lower electrode 120 or from the second lower electrode 120 to the first lower electrode 110. In this way, occurrence of the aforementioned bridge defects may be reduced or minimized.

Referring to FIG. 6, the capacitor structure 10 according to some of the embodiments of the present disclosure may include the upper interface layer 230 disposed between the upper electrode 150 and the dielectric layer 130. In at least one example, the upper interface layer 230 may include a conductive material. In at least one example, the upper interface layer 230 may include a third material. In at least one example, the third material may be the conductive material and may include nitrogen (N). In at least one example, the third material may include nitrogen (N) and oxygen (O). In at least one example, the upper interface layer 230 may include the third material that is the conductive material. In at least one example, the third material may include one or more of aluminum (Al), gallium (Ga), germanium (Ge), tin (Sn), silicon (Si), and/or boron (B).

The upper interface layer 230 may include a nitride or an oxynitride including M₄ and/or M₅. In at least one example, the M₄ may include one or more of titanium (Ti), vanadium (V), chromium (Cr), manganese (Mn), iron (Fe), cobalt (Co), nickel (Ni), copper (Cu), niobium (Nb), molybdenum (Mo), technetium (Tc), ruthenium (Ru), palladium (Pd), silver (Ag), cadmium (Cd), indium (In), antimony (Sb), tantalum (Ta), tungsten (W), rhenium (Re), osmium (Os), iridium (Ir), platinum (Pt), gold (Au), mercury (Hg), lead (Pb), bismuth (Bi), and/or polonium (Po). In at least one example, the M₄ may include one or more of titanium (Ti), niobium (Nb), and/or molybdenum (Mo). In at least one example, the M₅ may include one or more of aluminum (Al), gallium (Ga), germanium (Ge), tin (Sn), silicon (Si), and/or boron (B).

In at least one example, the upper interface layer 230 may include the M₄ in an amount of 10 at % or less, 9 at % or less, 8 at % or less, 7 at % or less, 6 at % or less, or 5 at % or less relative to the total number of elements of the M₄ and M₅. In this way, in the capacitor structure 10, the upper interface layer 230 may reduce leakage current and/or prevent leakage current from increasing while maintaining conductivity.

In at least one example, the M₁ included in the lower interface layer 210 and the M₄ included in the upper interface layer 230 may be the same element. In at least one example, the M₃ included in the lower interface layer 210 and the M₅ included in the upper interface layer 230 may be the same element.

In at least one example, the M₁ included in the lower interface layer 210 and the M₄ included in the upper interface layer 230 may be different elements. In at least one example, the M₃ included in the lower interface layer 210 and the M₅ included in the upper interface layer 230 may be different.

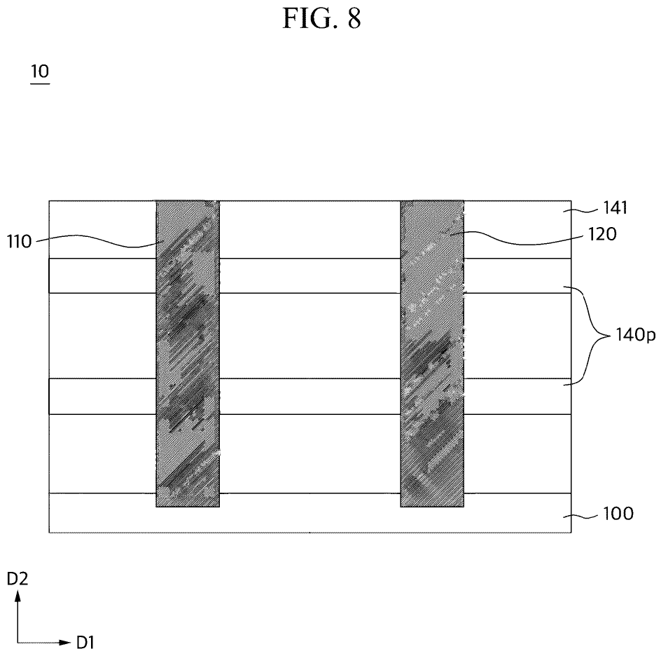

FIGS. 8 to 13 are views for describing a method of manufacturing a capacitor structure 10 according to an embodiment of the present disclosure. Hereinafter, the description of the method of manufacturing the capacitor structure 10 may refer to the above-described contents described through FIGS. 1 to 7, unless contradictory; and therefore, repeat descriptions may be omitted for brevity.

Referring to FIG. 8, in at least one example, a method of manufacturing the capacitor structure 10 may include forming a lower electrode passing through a supporter film 140p and a mold film 141. In at least some embodiments, the supporter film 140p and a mold film 141 may be on the substrate structure 100 and a pattern formed in the supporter film 140p and a mold film 141 (e.g., through etching); and then the lower electrode may be formed in the pattern. In at least one example, the supporter film 140p and the mold film 141 may be in contact with a portion of the side walls of the first lower electrode 110 and the second lower electrode 120, but are not limited thereto. In at least one embodiment, the lower electrode may include the first lower electrode 110 and the second lower electrode 120. In at least one example, the first lower electrode 110 and the second lower electrode 120 may be formed to extend to be long in the second direction D2. In at least one example, each of the first lower electrode 110 and the second lower electrode 120 may be formed to have, for example, a pillar-shaped shape. In at least one example, each of the first lower electrode 110 and the second lower electrode 120 spaced apart from the first lower electrode 110 may include the aforementioned M₁.

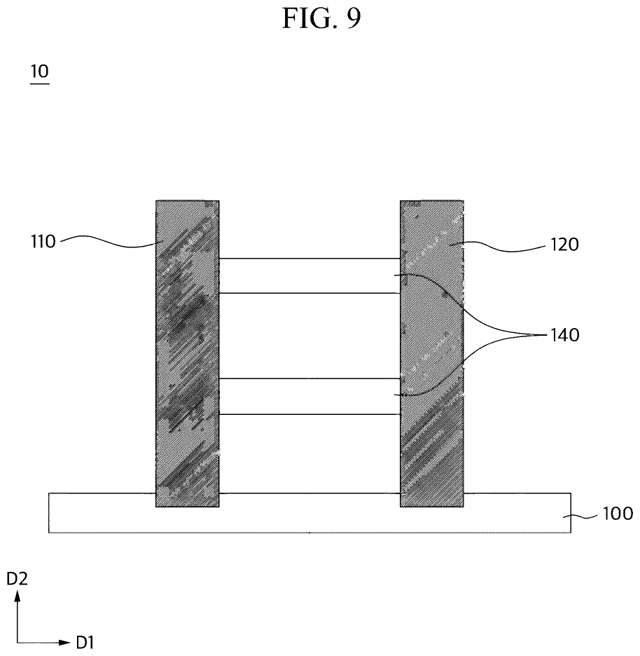

Referring to FIG. 9, in at least one example, a method of manufacturing the capacitor structure 10 may include removing a portion of the supporter film 140p to form the supporter 140 connecting adjacent lower electrodes 110 and 120. There may be one or two or more supporters 140, and in the case of two or more, each supporter 140 may be formed to be spaced apart from the other in the second direction D2. In at least one example, the mold film 141 may be removed from a region excluding the first lower electrode 110, the second lower electrode 120, and the supporter 140 connecting the first lower electrode 110 and the second lower electrode 120. The mold film 141 may be removed, for example, through an etching process. In this way, the supporter 140 connecting adjacent lower electrodes may be formed, and an empty space may be formed between the first lower electrode 110, the second lower electrode 120, and the supporter 140.

In at least one example, the method of manufacturing the capacitor structure 10 may include forming a lower electrode including the first lower electrode 110 including the M₁ and the second lower electrode 120 spaced apart from the first lower electrode 110, and forming the supporter 140 with the first lower electrode 110 and the second lower electrode 120. In at least one example, as described above, the M₁ may include one or more of titanium (Ti), vanadium (V), chromium (Cr), manganese (Mn), iron (Fe), cobalt (Co), nickel (Ni), copper (Cu), niobium (Nb), molybdenum (Mo), technetium (Tc), ruthenium (Ru), palladium (Pd), silver (Ag), cadmium (Cd), indium (In), antimony (Sb), tantalum (Ta), tungsten (W), rhenium (Re), osmium (Os), iridium (Ir), platinum (Pt), gold (Au), mercury (Hg), lead (Pb), bismuth (Bi), and/or polonium (Po). In at least one example, the M₁ may include one or more of titanium (Ti), niobium (Nb), and/or molybdenum (Mo).

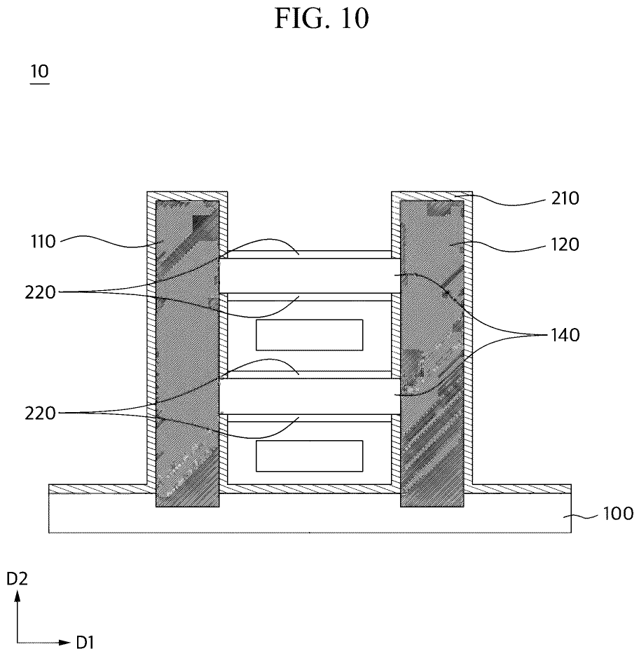

Referring to FIG. 10, in at least one example, the method of manufacturing the capacitor structure 10 may include forming a lower interface layer 210 and a supporter interface layer 200. The lower interface layer 210 and the supporter interface layer 220 may be, respectively, a first nitride layer 210 including the M₃ disposed on the lower electrodes 110 and 120, and a second nitride layer 220 including the M₂ disposed on the supporter 140. For ease of reference, the lower interface layer 210 and the supporter interface layer 220 may be, respectively, referred to as a first nitride layer 210 and a second nitride layer 220 in the following description. The first nitride layer 210 may be the lower interface layer 210 described above, and the second nitride layer 220 may be the supporter interface layer 220 described above. In at least one example, the first nitride layer 210 may include a nitride including the M₃. In at least one example, the second nitride layer 220 may include a nitride including the M₂.

In at least one example, the M₂ and M₃ may each independently include one or more of aluminum (Al), gallium (Ga), germanium (Ge), tin (Sn), silicon (Si), and/or boron (B), as described above.

That is, in at least one example, the method of manufacturing the capacitor structure 10 may include forming the first nitride layer 210 disposed on the first lower electrode 110 and the second lower electrode 120 and forming the second nitride layer 220 disposed on the supporter 140. In at least one example, the first nitride layer 210 and the second nitride layer 220 may be simultaneously formed. In at least one example, the first nitride layer 210 may be formed first and then the second nitride layer 220 may be formed, or the second nitride layer 220 may be formed first and then the first nitride layer 210 may be formed. In at least one example, the first nitride layer 210 and the second nitride layer 220 may be formed through deposition. In the present specification, deposition may be performed through various methods such as chemical vapor deposition (CVD), physical vapor deposition (PVD), atomic layer deposition (ALD), or the like. In at least one example, the first nitride layer 210 and the second nitride layer 220 may be formed optionally through atomic layer deposition. In at least one example, the components of the capacitor structure 10 may be formed, for example, through deposition, unless otherwise specified, but are not limited thereto. In at least one example, the first nitride layer 210 and the second nitride layer 220 may each have insulating properties.

In at least one example, the first nitride layer 210 may from the lower interface layer 210 including the M₁ and M₃ by diffusing the M1 included in the lower electrodes 110 and 120 through a heat treatment process to be described below. Thereby, the lower interface layer 210 may have conductivity. In at least one example, the lower interface layer 210 may include a nitride or an oxynitride including the M₁ and M₃. That is, in at least one example, the method of manufacturing the capacitor structure 10 may convert the insulating first nitride layer 210 into the conductive lower interface layer 210 through the heat treatment process.

In at least one example, the second nitride layer 220 may be the supporter interface layer 220. The supporter interface layer 220 may have insulating properties.

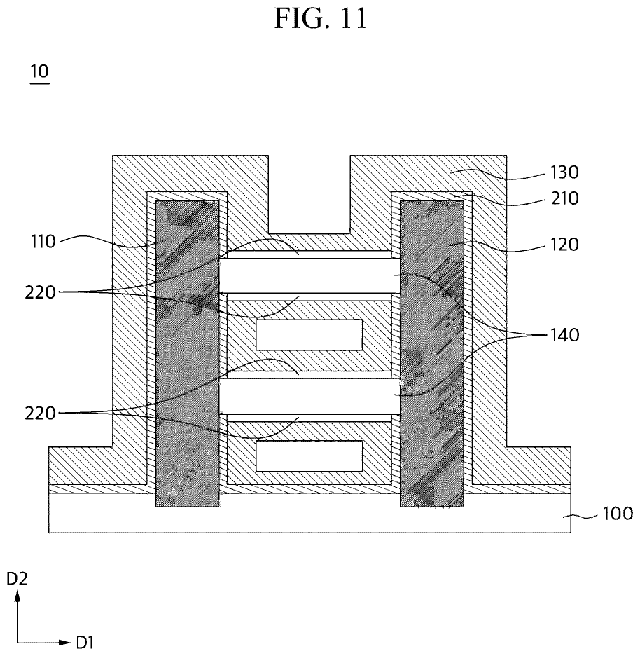

Referring to FIG. 11, in at least one example, the method of manufacturing the capacitor structure 10 may include forming the dielectric layer 130 on the first nitride layer 210 and the second nitride layer 220. In at least one example, the dielectric layer 130 may be formed on at least a portion of each of the first nitride layer and the second nitride layer 220. In at least one example, the dielectric layer 130 may be formed along a profile of the first nitride layer 210 and the second nitride layer 220.

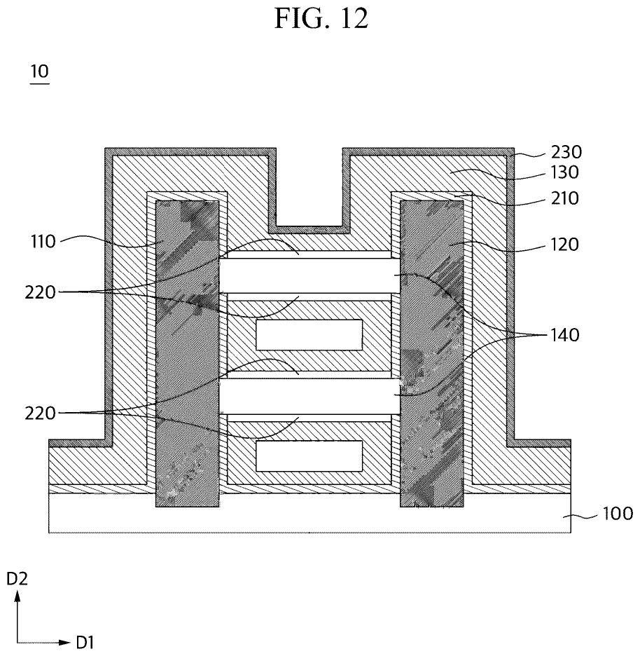

Referring to FIG. 12, in at least one example, the method of manufacturing the capacitor structure 10 may include forming the upper interface layer 220 on the dielectric layer 130. In at least one example, the upper interface layer 220 may be formed along a profile of the dielectric layer 130.

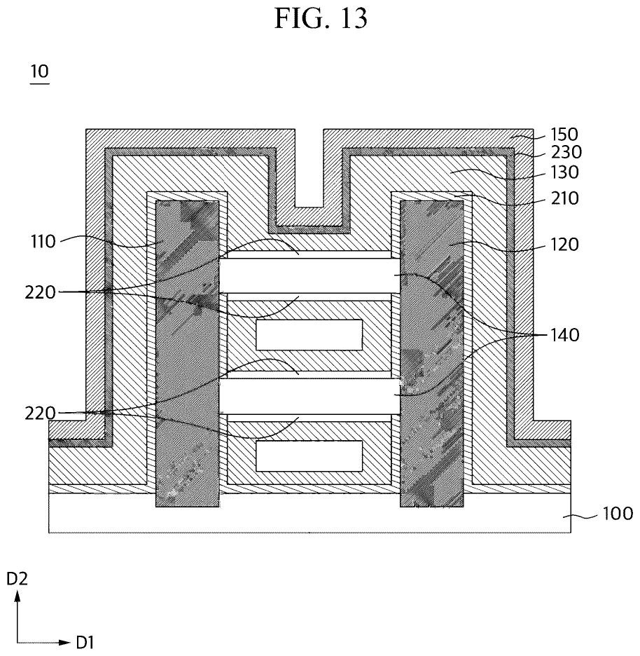

Referring to FIG. 13, in at least one example, the method of manufacturing the capacitor structure 10 may include forming the upper electrode 150 on the dielectric layer 130. In at least one example, the method of manufacturing the capacitor structure 10 may include forming the upper electrode 150 on the upper interface layer 220. In at least one example, the upper electrode 150 may be formed along a profile of the upper interface layer 220.

The method of manufacturing a capacitor structure 10 according to at least one embodiment of the present disclosure may further include diffusing the M₁ included in the lower electrode into the first nitride layer 210. In at least one example, the method may include diffusing the M₁ included in the first lower electrode 110 and the second lower electrode 120 away from a region adjacent to the first lower electrode 110 and the second lower electrode 120 of the first nitride layer 210.

In at least one example, the diffusing may include forming the first nitride layer 210 as the lower interface layer 210 including a nitride or an oxynitride including the M₁ and M₃, and forming the second nitride layer 220 as the supporter interface layer 220 including a nitride or an oxynitride including the M₂.

In at least one example, diffusion of the M₁ may be achieved by the heat treatment process. In at least one example, the heat treatment process may be performed at 500° C., 550° C., 600° C., 650° C., 700° C., or higher, but is not limited thereto, and may be, for example, performed at a temperature selected to diffuse the M₁ of the lower electrode into the first nitride layer 210. In at least one example, the heat treatment process may be performed prior to forming the dielectric layer 130.

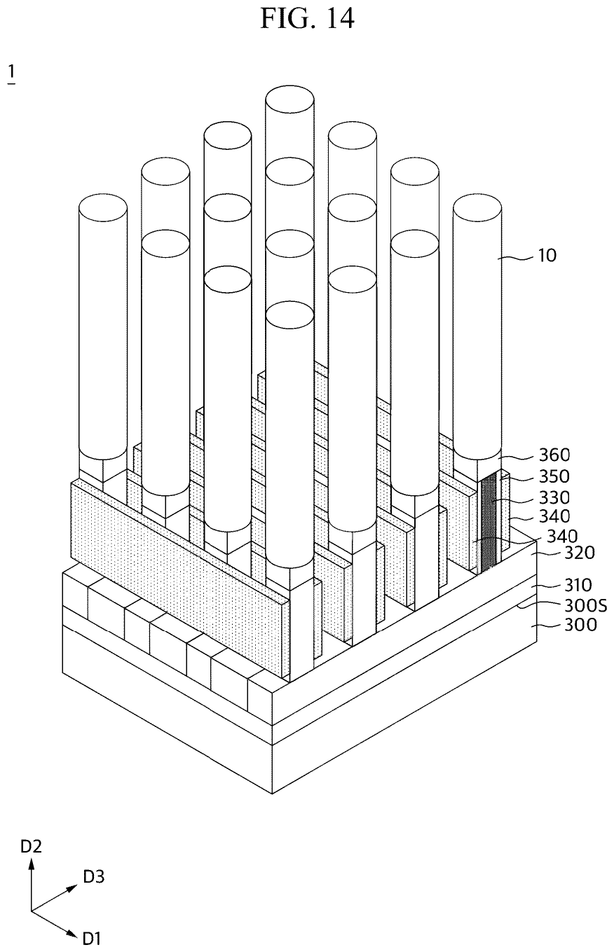

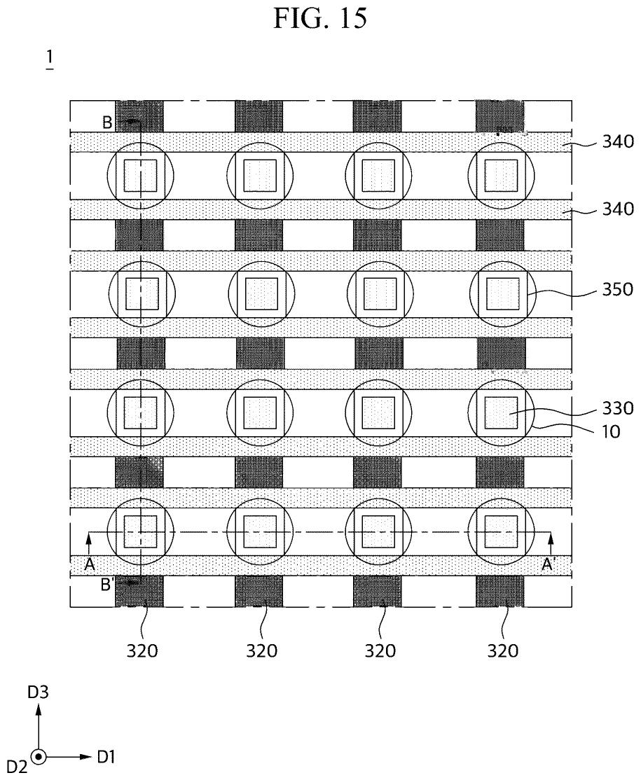

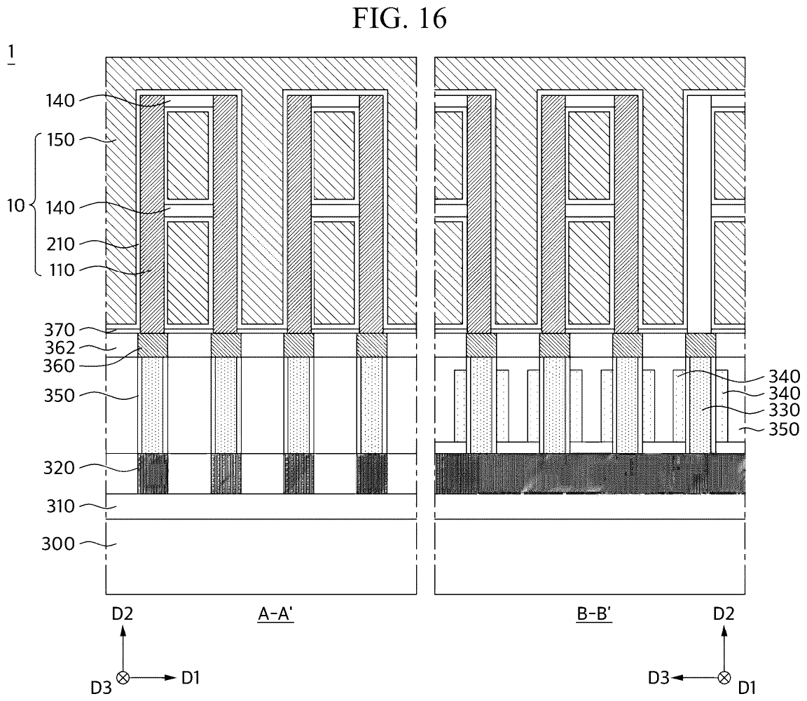

FIG. 14 schematically illustrates at least a portion of a memory device 1 according to at least one embodiment of the present disclosure. FIG. 15 schematically illustrates at least a portion of the memory device 1 according to at least one embodiment of the present disclosure. FIG. 16 is a cross-sectional view taken along lines A-A′ and B-B′ in FIG. 15.

In at least one example, the memory device 1 may include a substrate 300, a conductive line 320, a channel layer 330, a gate electrode 340, a gate insulating layer 350, a capacitor contact 360, and a capacitor structure 10. In at least one example, the memory device 1 may include a vertical channel transistor (VCT). In at least one example, the vertical channel transistor may refer to a transistor having a structure in which the channel layer 330 extends from a surface of the substrate 300 in a vertical direction (that is, a second direction D2).

The capacitor structure 10 in FIGS. 14 to 16 may refer to the description of the capacitor structure 10 in FIGS. 1 to 13, unless otherwise contradictory. FIG. 14 omits the supports 140 and the upper electrode 150 for clarity. Meanwhile, the substrate 300 may refer to the contents of the aforementioned substrate structure 100 unless otherwise contradictory.

In at least one example, a first direction D1 may be a direction parallel to a surface 300S of the substrate, as illustrated in FIG. 14. The second direction D2 may refer to a direction intersecting the first direction D1, and specifically, the second direction D2 may be a direction perpendicular to the surface 300S of the substrate while intersecting the first direction D1, as illustrated in FIG. 14. A third direction D3 may be a direction that intersects the first direction D1 as illustrated in FIG. 14, but is parallel to the surface 300S of the substrate.

In at least one example, an insulating layer 310 may be disposed on the substrate 300, and a plurality of conductive lines 320 may be spaced apart from each other in the first direction D1 and extended in the third direction D3 on the insulating layer 310. In at least one example, a space between the plurality of conductive lines 320 may be filled with an insulating material. In at least one example, the plurality of conductive lines 320 may function as bit lines of the memory device 1.

In at least one example, the plurality of conductive lines 320 may include a conductive material, such as doped polysilicon, a metal, a conductive metal nitride, a conductive metal silicide, a conductive metal oxide, and/or a combination thereof. For example, the plurality of conductive lines 320 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, and/or a combination thereof, but are not limited thereto. In at least one example, the plurality of conductive lines 320 may include a single layer or multiple layers of the materials described above. In at least one example, the plurality of conductive lines 320 may include a two-dimensional conductor and/or a two-dimensional semiconductor material, for example, the two-dimensional material may include graphene, carbon nanotubes, or a combination thereof.

In at least one example, the channel layers 330 may be disposed in a matrix form to be spaced apart from each other in the first direction D1 and the third direction D3 on the plurality of conductive lines 320. In at least one example, the channel layer 330 may have a first width along the first direction D1 and a first height along the second direction D2, and the first height may be greater than the first width. For example, the first height may be about 2 to 10 times the first width, but is not limited thereto. In at least one example, a lower portion of the channel layer 330 may function as a first source/drain region (not shown), and an upper portion of the channel layer 330 may function as a second source/drain region (not shown). In at least one example, a portion of the channel layer 330 between the first source/drain region and the second source/drain region may function as a channel region (not shown) through which electrons or holes move.

In at least one example, the channel layer 330 may include an oxide semiconductor. In at least one example, the channel layer may include, for example, the oxide semiconductor InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, and/or a combination thereof. In at least one example, the channel layer 330 may include a single layer or multiple layers of the oxide semiconductor. In at least one example, the channel layer 330 may have a band gap energy equal to or greater than a band gap energy of silicon. In at least one example, the channel layer 330 may have a band gap energy, for example, of about 1.5 eV to 5.6 eV or a band gap energy of about 2.0 eV to 4.0 eV. In at least one example, the channel layer 330 may be polycrystalline or amorphous, but is not limited thereto. In at least one example, the channel layer 330 may include a two-dimensional semiconductor material, for example, the two-dimensional semiconductor material may include one or more of MoS₂, doped graphene, carbon nanotubes, and/or the like.

In at least one example, the gate electrode 340 may extend in the first direction D1 on both sidewalls of the channel layer 330. In at least one example, the gate electrode 340 may include a conductive material, such as doped polysilicon, a metal, a conductive metal nitride, a conductive metal silicide, a conductive metal oxide, or a combination thereof. For example, the gate electrode 340 may be formed of a conductive material, such as doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, and/or a combination thereof, but is not limited thereto.

In at least one example, the gate insulating layer 350 may surround at least a portion of a sidewall of the channel layer 330, and may be interposed between the channel layer 330 and the gate electrode 340. In at least one example, the entire sidewall of the channel layer 330 may be surrounded by the gate insulating layer 350, and a portion of the sidewall of the gate electrode 340 may be in contact with the gate insulating layer 350.

In at least one example, the gate insulating layer 350 may extend in an extension direction of the gate electrode 340 (that is, the first direction D1), and only two of sidewalls of the channel layer 330 facing the gate electrode 340 may be in contact with the gate insulating layer 350.

In at least one example, the gate insulating layer 350 may be formed of an insulating material, such as one or more of a silicon oxide film, a silicon oxynitride film, a high-k dielectric film having a higher dielectric constant than the silicon oxide film, and/or the like. In at least one example, the high-k dielectric film may be formed of a metal oxide or a metal oxynitride. In at least one example, the high-k dielectric film usable as the gate insulating layer 350 may be formed of one or more of HfO₂, HfSiO, HfSiON, HfTaO, HfTiO, HfZrO, ZrO₂, and/or Al₂O₃, but is not limited thereto.

In at least one example, the capacitor contact 360 may be disposed on the channel layer 330. The capacitor contacts 360 may be disposed to overlap the channel layer 330 when viewed in the second direction D2 and arranged in a matrix form to be spaced apart from each other in the first direction D1 and the third direction D3. In at least one example, the capacitor contact 360 may be formed of a conductive material, such as one or more of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, and/or RuOₓ, but is not limited thereto.

In at least one example, an etch stop film 370 may be disposed on an upper insulating layer 362, and the capacitor structure 10 may be disposed on the etch stop film 370. In at least one example, the capacitor structure 10 may include the lower electrode, the dielectric layer 130, and the upper electrode 150.

In at least one example, the lower electrode may pass through the etch stop film 370 to be electrically connected to an upper surface of the capacitor contact 360. The lower electrode may be formed in a pillar type extending in the second direction D2, but is not limited thereto. In at least one example, the lower electrodes may be disposed to overlap the capacitor contact 360 when viewed in the second direction D2 and arranged in a matrix form to be spaced apart from each other in the first direction D1 and the third direction D3. Alternatively, a landing pad (not shown) may be further disposed between the capacitor contact 360 and the lower electrode so that the lower electrode is arranged in a hexagonal shape.

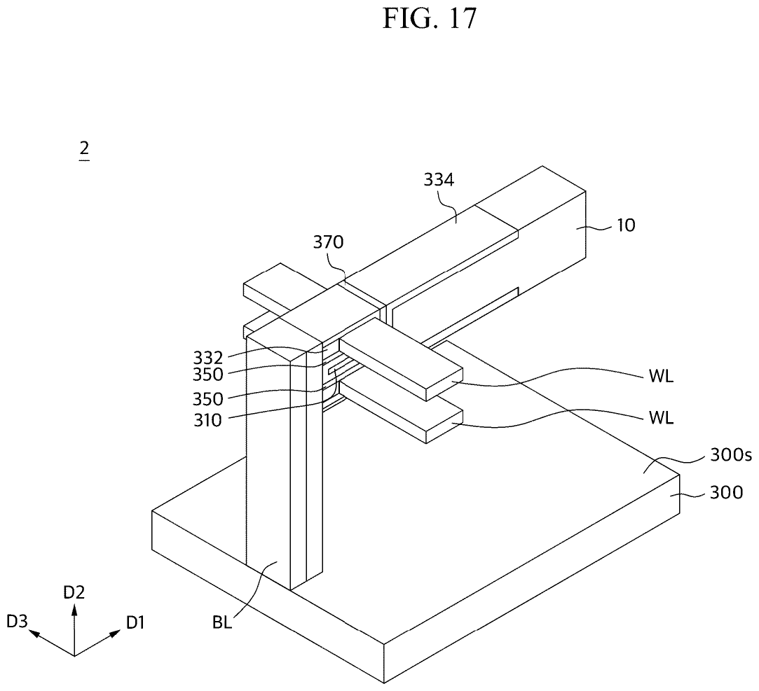

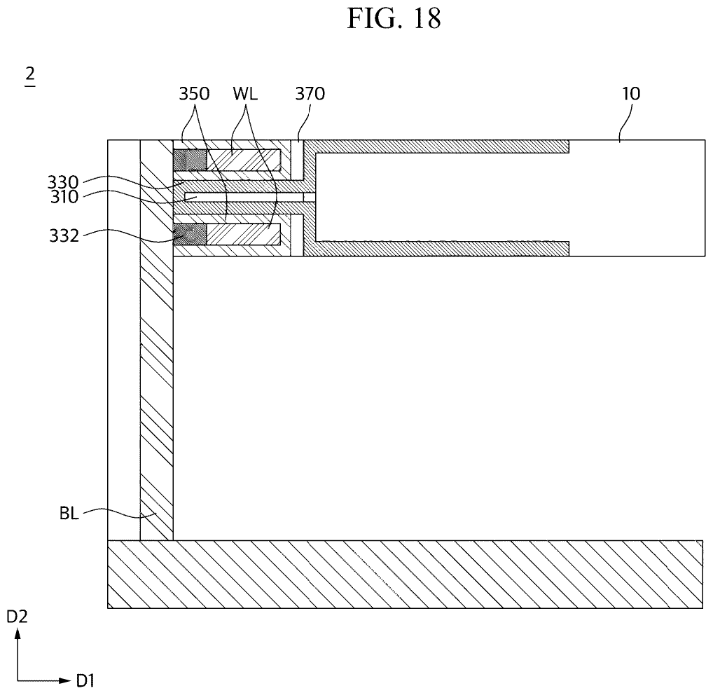

FIG. 17 schematically illustrates at least a portion of a memory device 2 according to at least one embodiment of the present disclosure. FIG. 18 schematically illustrates at least a portion of the memory device 2 according to at least one embodiment of the present disclosure.

In at least one example, a first direction D1 may be a direction parallel to a surface 300S of a substrate, as illustrated in FIG. 17. A second direction D2 may refer to a direction intersecting the first direction D1, and specifically, the second direction D2 may be a direction perpendicular to the surface 300S of the substrate while intersecting the first direction D1, as illustrated in FIG. 17. A third direction D3 may be a direction that intersects the first direction D1 as illustrated in FIG. 17, but is parallel to the surface 300S of the substrate. In at least one example, the memory device 2 may include the substrate 300, an insulating layer 310, a channel layer 330, a gate insulating layer 350, a word line WL, a bit line BL, and a capacitor structure 10. In at least one example, the memory device 2 may have a vertical stacked structure. In at least one example, the vertically stacked structure may refer to a structure including a plurality of memory devices 2 arranged in three dimensions, at least some of the plurality of memory devices 2 being stacked along the second direction D2, and a channel layer 330 extending along a side surface of the word line WL and a surface extending in a direction away from the bit line BL. In at least one example, the plurality of memory devices 2 may be stacked in a stacking direction (for example, in the second direction D2), a gap may exist between adjacent memory devices 2, and an insulating film may be disposed between the gaps.

The capacitor structure 10 in FIGS. 17 and 18 may refer to the description of the capacitor structure 10 in FIGS. 1 to 13, unless otherwise contradictory.

In at least one example, each memory device 2 may be connected to one bit line BL and two word lines WL. In at least one example, the bit line BL may extend along the second direction D2. In at least one example, there may be a plurality of bit lines BL, and the plurality of bit lines BL may be arranged along the first direction D1. In at least one example, a plurality of bit lines BL may be arranged along the third direction D3. In at least one example, adjacent bit lines BL among the disposed bit lines BL may be insulated from each other by having an insulating film disposed between the bit lines.

In at least one example, the bit line BL may be electrically connected to the channel layer 330. The bit line BL may be in contact with the channel layer 330.

In at least one example, the word line WL may extend along the third direction D3. In at least one example, there may be a plurality of word lines WL, and the plurality of word lines WL may be arranged along the first direction D1 while being spaced apart from each other in the second direction D2.

In at least one example, a spacer 332 may be disposed between the word line WL and the bit line BL. In at least one example, the spacer 332 may include an insulating material and insulate the bit line BL and the word line WL from each other.

In at least one example, the gate insulating layer 350 may surround at least a portion of a surface of the word line WL. In at least one example, the gate insulating layer 350 may conformally surround the word line WL. In at least one example, the gate insulating layer 350 may surround at least a portion of each of upper, side, and lower surfaces of the word line WL. In at least one example, the gate insulating layer 350 may surround a surface of the spacer 332. In at least one example, the gate insulating layer 350 may surround at least a portion of each of upper and lower surfaces of the spacer 332.

In at least one example, the gate insulating layer 350 may be connected to the bit line BL. In at least one example, a portion of the gate insulating layer 350 covering the upper surface of the spacer 332 and a portion of the gate insulating layer 350 covering the lower surface of the spacer 332 may be connected to the bit line BL.

In at least one example, the channel layers 330 arranged in the second direction D2 may be insulated by an interlayer insulating film (not shown).

In at least one example, the channel layer 330 may be disposed between facing surfaces of two adjacent word lines WL in the second direction D2. In at least one example, the channel layer 330 may be separated from the word lines WL by two gate insulating layers 350.

In at least one example, the channel layer 330 may be connected to the bit line BL between two adjacent word lines WL in the second direction D2. In at least one example, a region of the channel layer 330 surrounding at least a portion of the two gate insulating layers 350 may be connected by a region of the channel layer 330 surrounding at least a portion of a side surface of the bit line BL. In at least one example, the channel layer 330 may conformally surround one surface of the gate insulating layer 350 and the side surface of the bit line BL.

In at least one example, the insulating layer 310 may be disposed between regions of the channel layer 330 surrounding one surface of two gate insulating layers 350. In at least one example, the gate insulating layer 350, the channel layer 330, the insulating layer 350, the channel layer 330 and the gate insulating layer 350 may be sequentially positioned between two adjacent word lines WL in a cross-section cut in the second direction D2. In at least one example, the channel layer 330 may be disposed between the insulating layer 310 and the bit line BL in a cross-section cut in the first direction D1.

In at least one example, the channel layer 330 may be separated from a side surface of the word line WL by the gate insulating layer 350 and the etch stop film 370.

In at least one example, the etch stop film 370 may be positioned on one side of the word lines WL. The gate insulating layers 350 may be disposed between the etch stop film 370 and the word lines WL. In at least one example, the etch stop film 370 may surround at least a portion of a side surface of the gate insulating layer 350. In at least one example, the etch stop film 370 may extend in the second direction D2.

In at least one example, the channel layer 330 covers at least one surface of the gate insulating layer 350 and the etch stop film 370, and may extend over a side surface of the etch stop film 370. In at least one example, the channel layer 330 may surround the etch stop film 370 along the second direction D2.

In at least one example, the channel layer 330 may extend in the first direction D1 away from the bit line BL. In at least one example, the channel layer 330 may extend parallel to the substrate 300 along the surface of the capacitor structure 10. In at least one example, the channel layer 330 may be electrically connected to the capacitor structure 10.

The present disclosure can provide a capacitor structure having a relatively high electrostatic capacitance and reduced (or minimized) leakage current and a method of manufacturing the capacitor structure.

Effects of the present disclosure are not limited to those mentioned above, and other effects not mentioned will be clearly understood by those skilled in the art from the description below.

In the above, the example embodiments of the present disclosure have been described with reference to the accompanying drawings, but, the present disclosure is not limited to the example embodiments and may be manufactured in various different forms and those of ordinary skill in the art to which the present disclosure pertains may understand that the additional or alternative example embodiments may be embodied in other specific forms without departing from the technical spirit or essential features of the present disclosure. Therefore, it is to be appreciated that the example embodiments described above are intended to be illustrative in all respects and not restrictive.

What is claimed IS:

1. A capacitor structure comprising:
a lower electrode including a first lower electrode and a second lower electrode;
an upper electrode;
a supporter in contact with the first lower electrode and the second lower electrode;
a dielectric layer between the lower electrode and the upper electrode;
a lower interface layer between the lower electrode and the dielectric layer, the lower interface layer including a first material; the first material being a conductor and including nitrogen (N); and
a supporter interface layer between the supporter and the dielectric layer, the supporter interface layer including a second material, the second material being an insulator and including nitrogen (N).

2. The capacitor structure of claim 1, wherein
the lower electrode includes a lower electrode metal element (M_{be}), and
the first material includes the lower electrode metal element (M_{be}).

3. The capacitor structure of claim 2, wherein in the lower interface layer, a concentration of the lower electrode metal element (M_{be}) gradually decreases with distance from the lower electrode.

4. The capacitor structure of claim 2, wherein the lower interface layer includes the lower electrode metal element (M_{be}) in an amount of 10 atomic percent (at %) or less relative to a total number of elements excluding nitrogen (N).

5. The capacitor structure of claim 2, wherein the lower electrode metal element (M_{be}) includes one or more of titanium (Ti), niobium (Nb), or molybdenum (Mo).

6. The capacitor structure of claim 1, wherein the first material and the second material each independently include one or more of aluminum (Al), silicon (Si), boron (B), or gallium (Ga).

7. The capacitor structure of claim 2, wherein the supporter interface layer includes the lower electrode metal element (M_{be}) in an amount of 0.1 atomic percent (at %) or less relative to a total number of elements excluding nitrogen (N).

8. The capacitor structure of claim 1, further comprising:
an upper interface layer between the upper electrode and the dielectric layer, the upper interface layer including a conductive material.

9. The capacitor structure of claim 1, wherein the lower interface layer and the supporter interface layer each independently have a thickness of 1 nm or less.

10. The capacitor structure of claim 1, wherein the supporter includes one or more of silicon nitride (SiN), silicon carbonitride (SiCN), silicon boron nitride (SiBN), silicon carbonate (SiCO), silicon oxynitride (SiON), silicon oxide (SiO), or silicon oxycarbonitride (SiOCN).

11. A memory device comprising:
the capacitor structure of claim 1; and
one or more transistors electrically connected to the capacitor structure.

12. A capacitor structure comprising:
a lower electrode including a first lower electrode and a second lower electrode;
an upper electrode;
a supporter in contact with the first lower electrode and the second lower electrode;
a dielectric layer between the lower electrode and the upper electrode;
a lower interface layer between the lower electrode and the dielectric layer, the lower interface layer including at least one of a nitride or an oxynitride including a first element (M₁); and
a supporter interface layer the supporter and the dielectric layer, the supporter interface layer including at least one of a nitride or an oxynitride including a second element (M₂),
wherein the M₁ includes one or more of titanium (Ti), vanadium (V), chromium (Cr), manganese (Mn), iron (Fe), cobalt (Co), nickel (Ni), copper (Cu), niobium (Nb), molybdenum (Mo), ruthenium (Ru), palladium (Pd), indium (In), antimony (Sb), tantalum (Ta), tungsten (W), iridium (Ir), platinum (Pt), gold (Au), or polonium (Po), and
the M₂ includes one or more of aluminum (Al), gallium (Ga), germanium (Ge), tin (Sn), silicon (Si), or boron (B).

13. The capacitor structure of claim 12, wherein the lower interface layer further a third element (M₃), and the M₃ includes one or more of aluminum (Al), gallium (Ga), germanium (Ge), tin (Sn), silicon (Si), or boron (B).

14. The capacitor structure of claim 13, wherein the M₃ is the same element as M₂.

15. The capacitor structure of claim 12, further comprising:
an upper interface layer between the upper electrode and the dielectric layer, the upper interface layer including at least one of a nitride or an oxynitride including a fourth element (M₄) and a fifth element (M₅),
wherein the M₄ includes one or more of titanium (Ti), vanadium (V), chromium (Cr), manganese (Mn), iron (Fe), cobalt (Co), nickel (Ni), copper (Cu), niobium (Nb), molybdenum (Mo), ruthenium (Ru), palladium (Pd), indium (In), antimony (Sb), tantalum (Ta), tungsten (W), iridium (Ir), platinum (Pt), gold (Au), or polonium (Po), and
the M₅ includes one or more of aluminum (Al), gallium (Ga), germanium (Ge), tin (Sn), silicon (Si), or boron (B).

16. A method of manufacturing a capacitor structure, comprising:
forming a lower electrode including a first lower electrode including a first element (M₁) and a second lower electrode spaced apart from the first lower electrode;
forming a supporter in contact with the first lower electrode and the second lower electrode;
forming a first nitride layer on the lower electrode;
forming a second nitride layer on the supporter;
forming a dielectric layer on the first nitride layer and the second nitride layer; and
forming an upper electrode on the dielectric layer;
wherein the method further comprises diffusing the M₁ included in the lower electrode into the first nitride layer,
the second nitride layer includes a second element (M₂),
the first nitride layer includes a third element (M₃),
the M₁ includes one or more of titanium (Ti), vanadium (V), chromium (Cr), manganese (Mn), iron (Fe), cobalt (Co), nickel (Ni), copper (Cu), niobium (Nb), molybdenum (Mo), ruthenium (Ru), palladium (Pd), indium (In), antimony (Sb), tantalum (Ta), tungsten (W), iridium (Ir), platinum (Pt), gold (Au), or polonium (Po), and
the M₂ and the M₃ each independently include one or more of aluminum (Al), gallium (Ga), germanium (Ge), tin (Sn), silicon (Si), or boron (B).

17. The method of claim 16, wherein the diffusing the M₁ includes forming the first nitride layer as a lower interface layer including at least one of a nitride or an oxynitride including M₁ and M₃ and forming the second nitride layer as a supporter interface layer including at least one of a nitride or an oxynitride including M₂.

18. The method of claim 16, wherein the diffusing includes performing a heat treatment process.

19. The method of claim 18, wherein the heat treatment process is performed at 500° C. or higher.

20. The method of claim 18, wherein the heat treatment process is performed prior to forming the dielectric layer.
